(19) United States
(12) Patent Application Publication
(10) Pub. No.: US 2025/0169243 A1
(43) Pub. Date: May 22, 2025

(54) LED WITH TRANSPARENT CONDUCTIVE STRUCTURE

(71) Applicant: Lumileds LLC, San Jose, CA (US)

(72) Inventors: Konstantin Andreas Engeter, Singapore (SG); Antonio Lopez-Julia, Vaals (NL); Shih Chun Liu, Singapore (SG)

(73) Assignee: Lumileds LLC, San Jose, CA (US)

(21) Appl. No.: 18/516,473

(22) Filed: Nov. 21, 2023

(51) Int. Cl. H01L 33/44; H01L 33/00; H01L 33/10; H01L 33/62

(52) U.S. Cl. CPC H10H 20/84; H10H 20/01; H10H 20/814; H10H 20/857; H10H 20/036

(57) ABSTRACT

Methods and devices including a die with a segmented transparent conductive oxide structure and/or a distributed bragg reflector (DBR) may improve optical efficiency and/or reflectivity of the system. The process of fabricating such a die has an improved workflow that may decrease the number of steps and/or masks used, such as by simultaneously depositing and/or patterning one or more structures in the die which may conventionally require more than one step. In this way, the luminous flux of the completed die is improved while the cost of production is decreased.

### FIELD OF THE INVENTION

The invention relates generally to light emitting devices, particularly LEDs with a segmented transparent conductive oxide structure.

### BACKGROUND

The automotive and general illumination industry has witnessed remarkable advancements in technology, with one breakthrough being the invention of Light-Emitting Diodes (LEDs). This innovation has transformed the way we perceive and experience automotive lighting and general illumination, offering improved efficiency, durability, and versatility. Developed as a response to the limitations of traditional light source, automotive LEDs have become a staple feature in modern vehicles, providing enhanced safety, aesthetics, and functionality.

In the world of automotive lighting and general illumination, the pursuit of increased luminous flux has been a constant endeavor. Luminous flux, a measure of the total amount of visible light emitted by a light source, directly influences the practical usefulness of LEDs.

The reflectivity of dies in LEDs are functions of many things, including the size of the contact region where the bonding or conductive layers contacts the n-side and p-side contacts. The geometry of such dies and the size of their openings influence the size of the reflective elements that are incorporated within them. Reducing the size of such openings or otherwise adjusting the geometry of the layers in the dies can allow an increase of the reflective elements and a decrease in the size of the absorptive or less reflective elements. Such adjustments may increase the overall reflectivity and optical efficiency of the system.

### SUMMARY

Embodiments of the invention introduces a novel approach to increase luminous flux of LEDs, while also being cost-efficient in production. Compatible with chip scale package (CSP) architectures, embodiments of the invention include a process of forming a die structure featuring a segmented transparent conductive oxide (TCO) structure and/or a distributed bragg reflector (DBR) mirror to increase the reflectivity of the die while maintaining low forward voltage V_{f}. That is, embodiments of the invention include am improved workflow that creates improved dies for LEDs. These dies may be used in automotive LEDs, general illumination LEDs, and any other LED applications which can use a CSP die.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display (e.g., AR/VR/MR) system.

FIG. 7 shows flow chart of a process of producing a die with a segmented transparent conductive oxide (TCO) structure according to embodiments of this invention.

FIG. 8 shows a cross section of a die with TCOs spaced apart from each other at the n-contact and the p-contact.

FIG. 9 shows a cross section of a die with TCOs spaced apart from each other at the n-contact and the p-contact and an extended metal reflector.

FIG. 10 shows a cross section of a die with TCOs spaced apart from each other at the n-contact and the p-contact with two distributed bragg reflectors (DBRs) spaced apart from each other.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “vertical” refers to a direction parallel to the force of the earth's gravity. The term “horizontal” refers to a direction perpendicular to “vertical.” The term “on” means to be disposed to overlap (e.g., vertically) and/or to be directly in contact with.

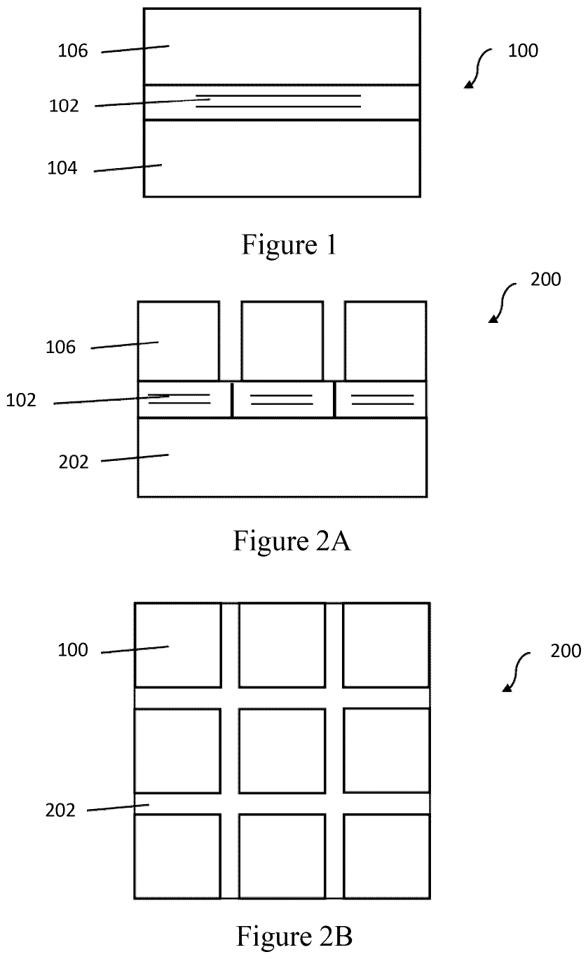

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material, or be or comprise a sintered ceramic phosphor plate.

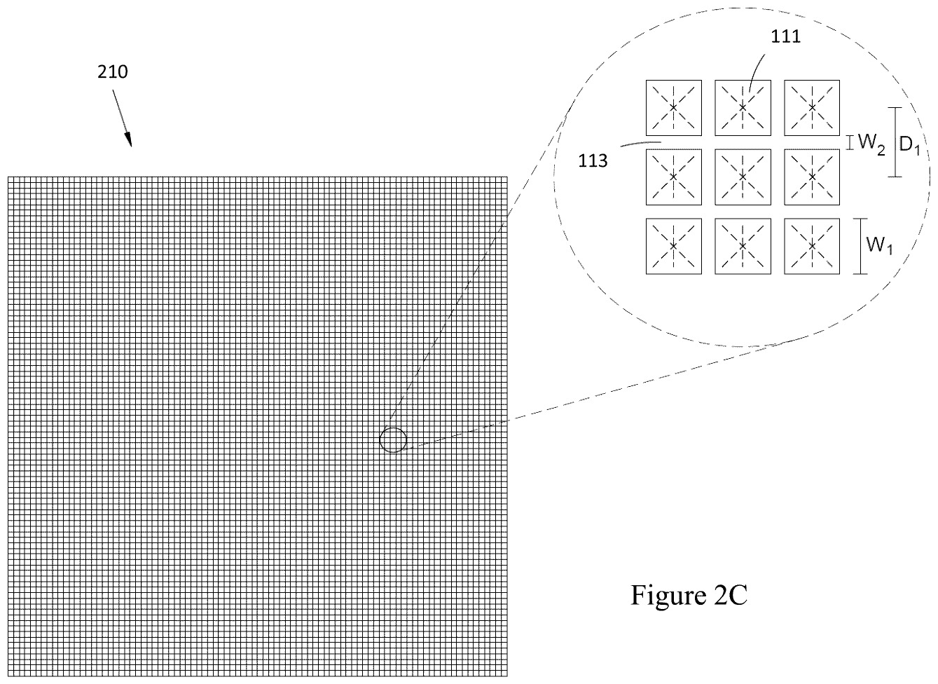

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from individual mechanically separate pcLEDs arranged on a substrate. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W1 are arranged as a square matrix with neighboring LEDs or pcLEDs having a center-to-center distances D1 and separated by lanes 113 having a width W2. W1 may be, for example, less than or equal to 1 millimeter (mm), less than or equal to 500 microns, less than or equal to 100 microns, less than or equal to 50 microns, or less than or equal to 10 microns. W2 may be, for example, hundreds of microns, less than or equal to 100 microns, less than or equal to 50 microns, less than or equal to 10 microns, or less than or equal to 5 microns. D1=W1+W2.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs having dimensions in the plane of the array (e.g., side lengths) of less than or equal to about 50 microns are typically referred to as microLEDs, and an array of such microLEDs may be referred to as a microLED array.

Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated from each other by trenches and/or insulating material, but the electrically isolated segments remain physically connected to each other by portions of the semiconductor structure.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

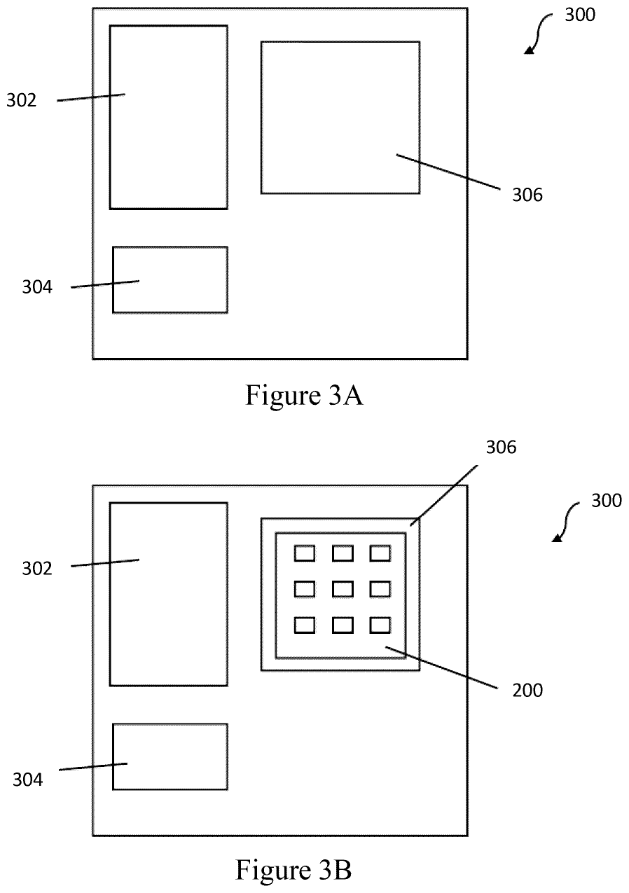

As shown in FIGS. 3A-3B, an LED or pcLED array 200 may be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

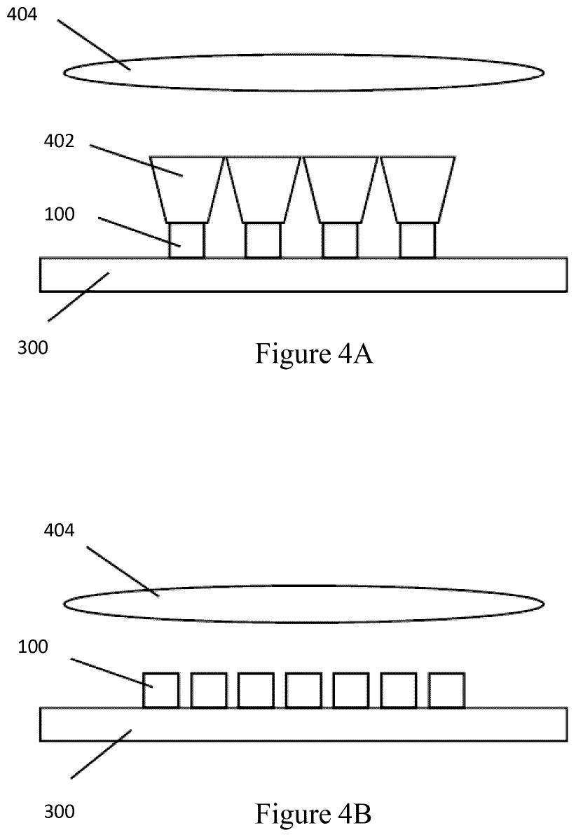

Individual LEDs or pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distribution. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), VR, and AR applications such as those described below.

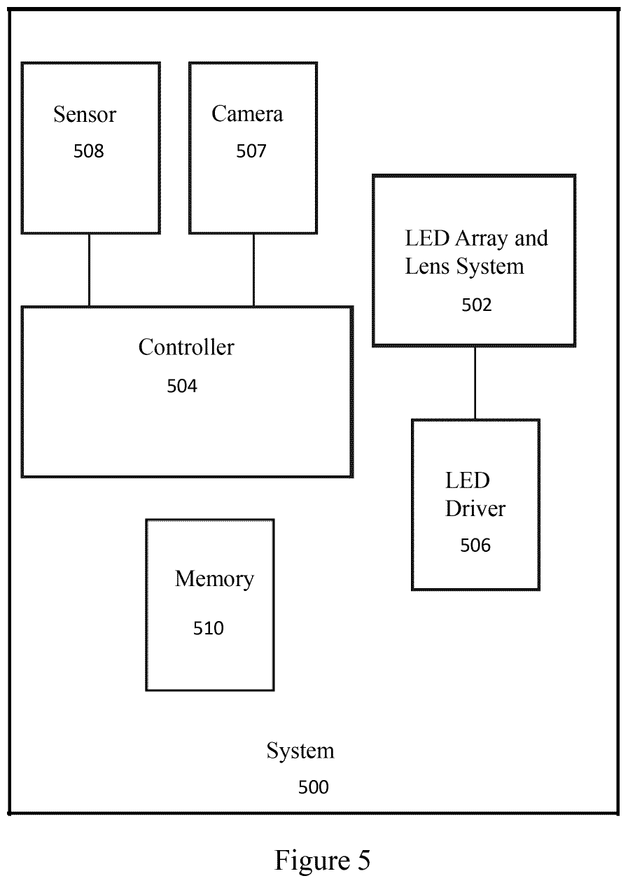

FIG. 5 schematically illustrates an example camera flash system 500 comprising an LED or pcLED array and lens system 502, which may be or comprise an adaptive lighting system as described above in which LEDs or pcLEDs in the array may be individually operable. In operation of the camera flash system, illumination from some or all of the LEDs or pcLEDs in array and lens system 502 may be adjusted-deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

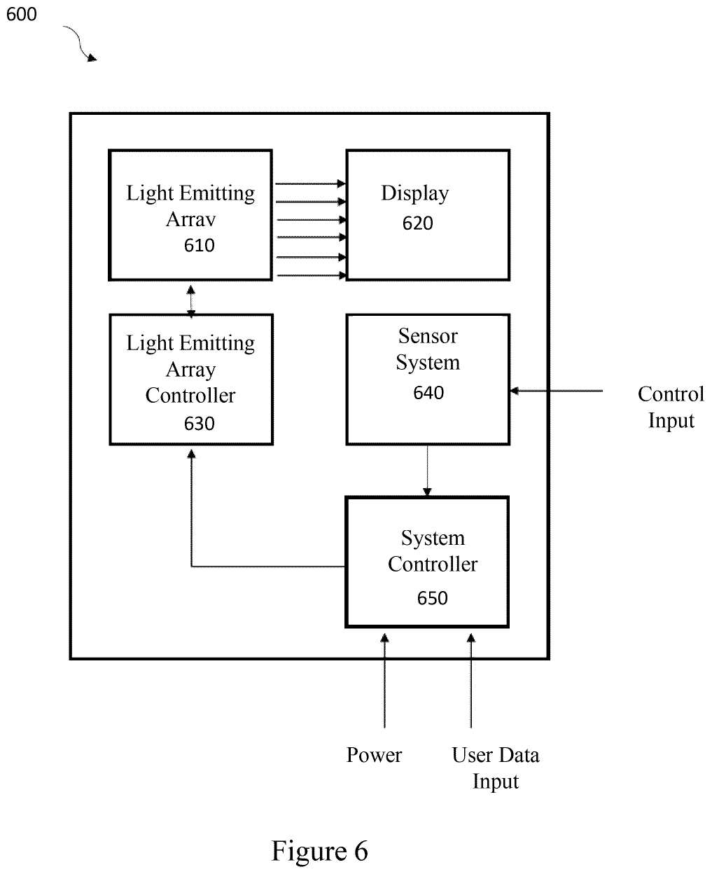

FIG. 6 schematically illustrates an example display (e.g., AR/VR/MR) system 600 that includes an array 610 of individually operable LEDs or pcLEDs, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Array 610 can be used to project light in graphical or object patterns that can support AR/VR/MR systems

Control input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

The above LEDs utilize dies whose flux, reflectivity and optical efficiency are dependent on the geometry of the layers and elements in the die. Improving the geometry of these elements will improve the light emitting efficiency of the LEDs as a whole.

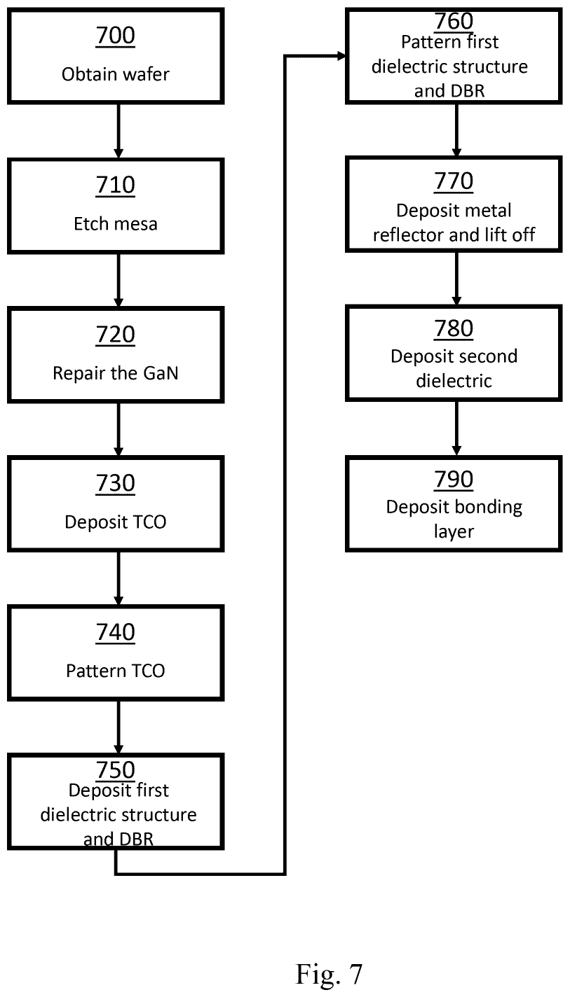

FIG. 7 shows a method for fabricating a die used in a light emitting device according to embodiments of the invention.

At 700, provide a wafer. The wafer may include a pGaN layer 810 on an nGaN layer 820. That is, the wafer may include a p-doped semiconductor material stacked with an n-doped semiconductor material.

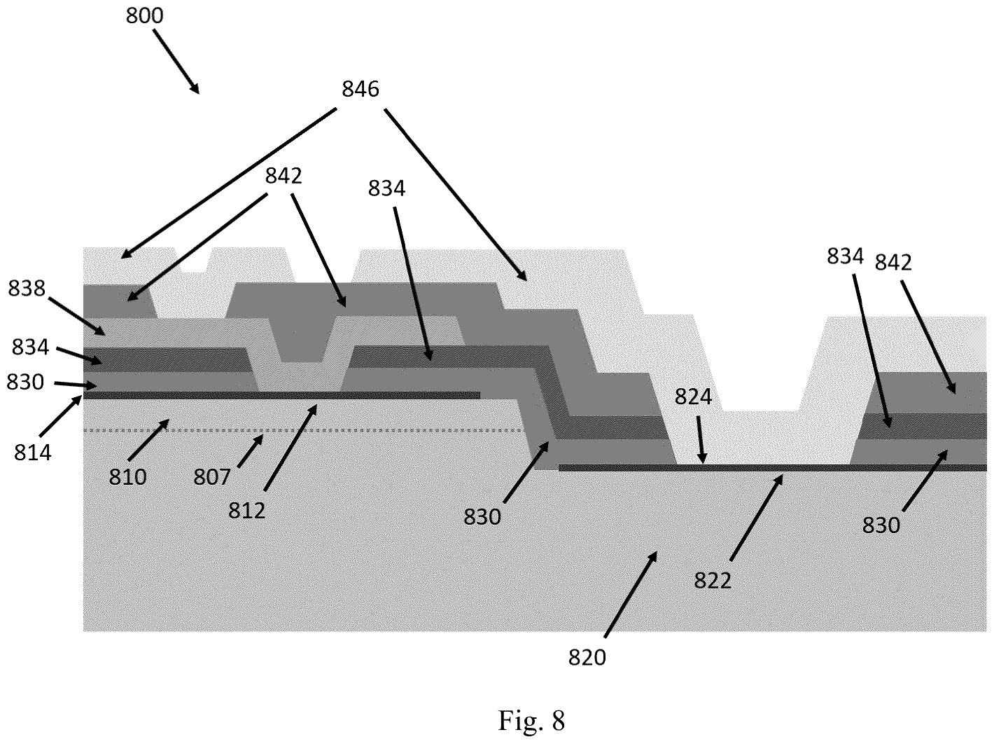

At 710, etch the mesa to expose an nGaN surface 822 (e.g., a surface of the n-doped semiconductor) which will be part of the n-contact. The etching may involve dry etching, and/or wet etching. This may involve removing part of the pGaN layer to expose an nGaN surface of the nGaN layer so that an electrical contact may be established on a horizontal, planar nGaN surface of the nGaN layer. Cutting into the nGaN layer forms a mesa whose top pGaN surface 812 is the pGaN layer, with mesa sidewalls extending down to the nGaN surface. This mesa is shown in FIG. 8. For example, the etching may create a mesa with a (vertical) height above the nGaN surface of 0.5-2 microns, e.g., 0.5-1 microns. The mesa may have sidewalls that are perpendicular or sloped at a non-perpendicular angle. Once this etching is done, the pGaN surface (e.g., a surface of the p-doped semiconductor) for forming the p-contact will be at the top of the mesa and the nGaN surface for forming the n-contact will be below the mesa, adjacent to the mesa sidewall.

At 720, repair the surface of the etched wafer, i.e. conduct GaN repair. After the mesa is etched, there may be damage on the pGaN and/or nGaN surfaces, particularly if dry etching was used to etch the mesa. There may be damage to the pGaN surface on top of the mesa and damage to the nGaN surface below the mesa. GaN repair is useful to ensure that a good ohmic contact with low resistivity can be formed at the p-contact and n-contact. GaN repair may include dry etching (which may be more fine-tuned than any dry etching used to form the mesa) the surface to clean up and/or polish the damage of the pGaN/nGaN surfaces. Since this GaN repair is done at an early stage of the process, and the TCO is deposited in the next step, this allows sealing of the surfaces used to form ohmic contacts early on by the TCO so that later steps will not react or further damage these surfaces.

At 730, deposit the TCO at the GaN surfaces and anneal to form ohmic contacts. The TCO may be deposited as one monolithic, continuous layer or structure directly contacting both the region of the p-contact and the region of the n-contact (i.e., the pGaN surface on top of the mesa and the nGaN surface below and adjacent to the mesa). That is, the TCO contacting the p-contact region and the n-contact region may be a same material and a same thickness as each other. For example, the material may be indium tin oxide (ITO), In₂O₃, ZnO, SnO₂, Ga₂O₃, CdO, or any other transparent conductive oxide. At this step, the TCO may be deposited on the entire surface of the etched wafer. The TCO may be a stepped structure extending from the pGaN surface down the sidewall of the mesa to the nGaN surface. The TCO may otherwise be flat at the pGaN surface and flat at the nGaN surface. In this case, flat may mean that the TCO has a largest plane which extends in the horizontal direction and/or is parallel to the nGaN and/or pGaN surfaces; flat may additionally or alternatively mean that the TCO has a largest surface facing away from the nGaN and/or pGaN surfaces which does not include any steps or changes in angles. After deposition, the TCO may be annealed at the p-contact region and the n-contact region so that the ohmic contacts in those respective regions are formed. Depositing and/or annealing the TCO at the p-contact region and the n-contact region simultaneously may save on production time and decrease the number of masks necessary to produce the die. Alternatively, the TCO at the p-contact region and the n-contact region may be deposited in two steps rather than one simultaneous step, and/or the TCO at the p-contact region may be or include a different material than the TCO at the n-contact region. Even in this case, however, the TCO at both the p-contact region and the n-contact region may be flat layers as defined above.

At 740, the TCO may be patterned (by dry or wet etching), e.g., to prevent shorting the n-contact TCO with the p-contact TCO. If the TCO was deposited as a monolithic, continuous, stepped structure extending from the top of the mesa to the bottom of the mesa, the TCO may be patterned by removing the stepped section of the TCO, which covers the edge of the mesa and the section adjacent to the edge, including a portion of the pGaN surface closest to the edge, an entire sidewall of the mesa, and a portion of the nGaN surface. Once this stepped section is removed, the p-side TCO 814 and the n-side TCO 824 are physically and electrically separated from each other. The respective TCOs may be flat, and n-side TCO may be vertically below the p-side TCO. The p-side TCO may extend throughout the whole p-contact region (i.e., where the metal reflector 838 directly contacts the p-side TCO as shown in FIG. 8) and the n-side TCO may extend throughout the whole n-contact region (i.e., where the bonding layer 846 directly contacts the n-side TCO as shown in FIG. 8).

Additionally or alternatively, the TCO may be patterned so that they are removed at places other than the stepped section mentioned above. This patterning may be done simultaneously with removal of the stepped section, so that production time is saved and fewer masks are used. For example, part of the p-side TCO which would otherwise be in contact with the metal reflector 838 (shown in FIG. 8) may be removed. When the metal reflector is deposited later on, it may be in direct contact with the pGaN surface rather than having the p-side TCO in between. This may improve optical efficiency of the system while still maintaining the TCO in the surrounding areas for current spreading.

To aid in the TCO patterning, alignment marks indicating where the TCO is to be patterned may have been placed at the mesa etching step 710. Patterning the TCO reduces the amount of TCO in the system, improving the optical efficiency of the system, while also having less current density close to the less reflective die edge and/or n-contact area.

At 750, deposit the first dielectric structure 830 and DBR. The first dielectric structure may be deposited to be in direct contact with the TCO at the n-side and the p-side, and/or to be in direct contact with the patterned opening of the TCO (e.g., the exposed edge and foot of the mesa, including part of the pGaN and nGaN surfaces). DBR 834 may be disposed on the first dielectric structure, in a simultaneous deposition step or a separate deposition step as the first dielectric structure. The first dielectric structure may include any dielectric, such as SiOₓ. The DBR may include multiple layers of dielectrics, each of which may be SiOₓ and/or TiOₓ. The first dielectric structure may be a thinner layer than the DBR, although this is not a requirement. The first dielectric structure may be at least ½ the wavelength of the light emitted by the semiconductor structure in thickness, and may be a low refractive index layer (e.g., compared to at least some layer of the DBR).

At 760, pattern the first dielectric structure and DBR so that the n-side TCO and the p-side TCO are at least partially exposed. This patterning at both the p-contact region and the n-contact region may be done simultaneously.

At 770, deposit a metal reflector 838 and lift off. The metal reflector may be deposited to be in direct contact with the DBR and in the openings created by the patterning of the first dielectric structure and DBR, i.e., the n-contact and the p-contact where the TCO is exposed. Once deposited, lift off may remove part of the metal reflector over the nGaN surface and part of the metal reflector over the pGaN surface, e.g., over the mesa edge and the region directly adjacent to the mesa edge. The metal reflector may be or comprise one or more of silver, nickel, and palladium. For example, the metal reflector may include one or more stacks of the aforementioned elements, such as stacks of Ag/Ni/Pd layered together. The metal reflector may furthermore comprise a layer of AlOₓ that is thinner compared to the metal in the metal reflector, which is used for adhesion purposes and because of its thinness has little to no impact on electrical performance of the metal reflector.

At 780, deposit a second dielectric structure 842 and open the structure by removing portions of the second dielectric structure (e.g. by etching) to expose materials under the second dielectric structure. The second dielectric structure may be or comprise pure SiOₓ. Opening may be done simultaneously at the p-side (over the pGaN surface at the mesa) and the n-side (over the nGaN surface below the mesa), so that two spatially separated openings are created at once. At the n-side, this creates an opening where the bonding layer will be able to contact the n-side TCO, and at the p-side this creates an opening where the bonding layer may contact the metal reflector. Usually there may be difficulties in opening the p-side and the n-side at once, because opening the p-side and n-side and the further cleaning steps involved may react with the exposed materials (e.g., with the nGaN surface if the TCO was not present). A solution would be to open the p-side and the n-side separately. This increases cost, because of the need to add one more masking, etching and cleaning step. In embodiments of the invention, since the GaN repair step has already been done very early in the flow and the repaired surface is being sealed off with the TCO from further impacts, it is possible to open the p-side and n-side at once, reducing cost of the workflow.

At 790, deposit a bonding layer 846. The bonding layer may be a stepped structure extending from the top of the second dielectric structure down to the n-side TCO, and may be in direct contact with the n-side TCO. The bonding layer may have two portions physically and electrically separated from each other, with one portion electrically connected to the n-side TCO and another portion electrically connected to the p-side TCO (e.g., through the metal reflector 838). The bonding layer may be or comprise one or more of silver, nickel, titanium, and copper. For example, the bondng layer may include one or more stacks of the aforementioned elements, such as stacks of Ag/Ni/Ti/Cu/Ti layered together. At this point, the rest of the flow may follow a typical chip-scale package (CSP) like flow.

FIG. 8 shows a die according to embodiments of this invention. The n-side TCO 824 spreads the current at the n-contact, making a smaller contact area to the contacting metal stack (i.e., the bonding layer 846) possible. Additionally or alternatively, it is also possible for adhesion reasons to have a very thin layer of dielectric material between the TCO and the bonding layer. In any case, the smaller contacting area is beneficial, because it allows the DBR to have an increased area as the contact area shrinks, which increases the reflectivity of the system.

The smaller size of the nContact area can also reduce the size the n Vias/DBR opening take up, and thus reduce the gaps needed at the UBM, which in turn can improve the Rth, leading to a better performance of the LED at higher temperatures. Smaller nVias enable new designs for the electrical layout. These new designs could increase current spreading homogeneity, which could benefit the LED with increased efficiency, flux and robustness.

Although this figure shows just one nContact and pContact area, a die according to embodiments of the inveniton may of course have multiple nContact and pContact areas. For example, a die may have one or more n-side TCOs spaced apart from each other, one or more p-side TCOs spaced apart from each other, one or more bonding layers spaced apart from each other, and one or more metal reflectors spaced apart from each other. In one example, the die may have a single continuous p-side TCO that is in direct contact with one or more metal reflectors, and a plurality of n-side TCOs each in direct contact with one or more bonding layers. That is, each of the n-side TCO and p-side TCO may be in direct contact with, respectively, multiple or a single bonding layers and multiple or a single metal reflectors. Each of the bonding layers may directly contact the one or more n-side TCOs with total contact areas smaller than an entire area of the respective bonding layer; the same is true with metal reflectors contacting the p-side TCOs. A metal reflector/bonding layer may directly contact the p-side TCO/n-side TCO at multiple contact areas spaced apart from and discontinuous with each other.

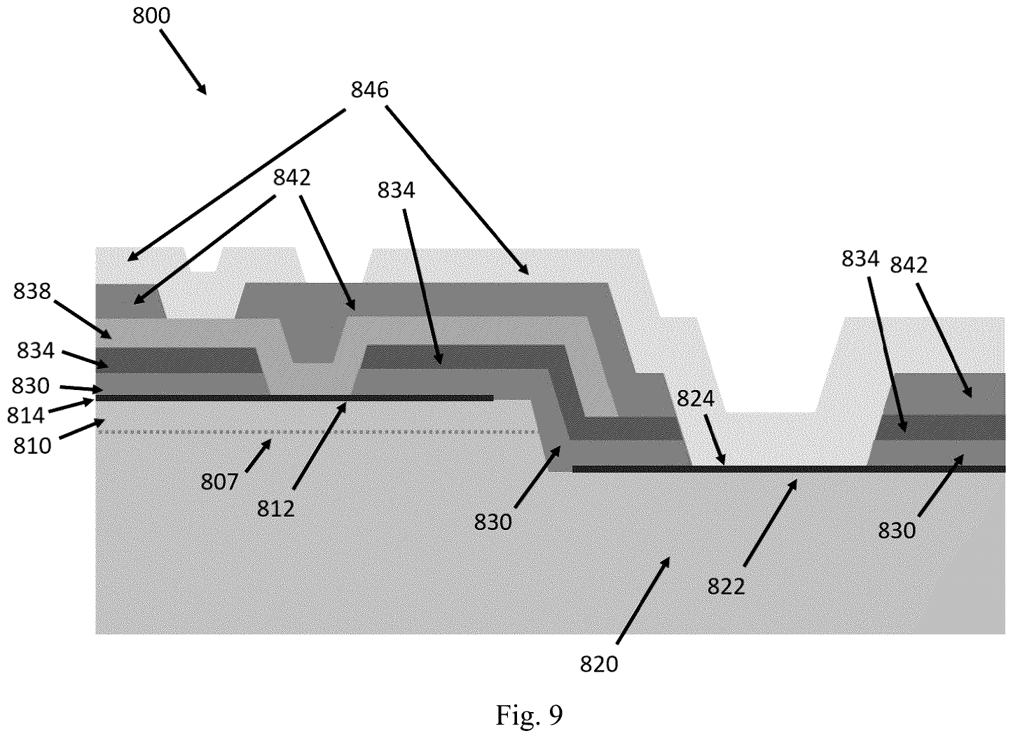

FIG. 9 shows a die according to embodiments of this invention. The metal reflector 838 extends over the pGaN surface 812 of the p-contact on the mesa all the way to the nGaN surface 822 below the mesa. The metal reflector may extend over the n-side TCO 822, which extends into the n-contact at the opening of the DBR 834, but may not extend over the n-contact itself. A portion of the metal reflector may extend horizontally up to or over the mesa edge, then angle downwards towards the nGaN surface below the mesa. The portion of the metal reflector angling downwards may extend below the mesa, i.e., below the pGaN surface in the vertical direction. The metal reflector may not extend all the way to the nGaN surface.

Because the space occupied by the dielectric structure 842 may be likely to trap and/or absorb photons, extending the metal reflector in the space between the dielectric and the DBR may help reflect these photons so that they are less likely to be absorbed and/or reach the quantum wells. The metal reflector may be one of the most reflective elements in the die and its extension may increase the optical efficiency of the system.

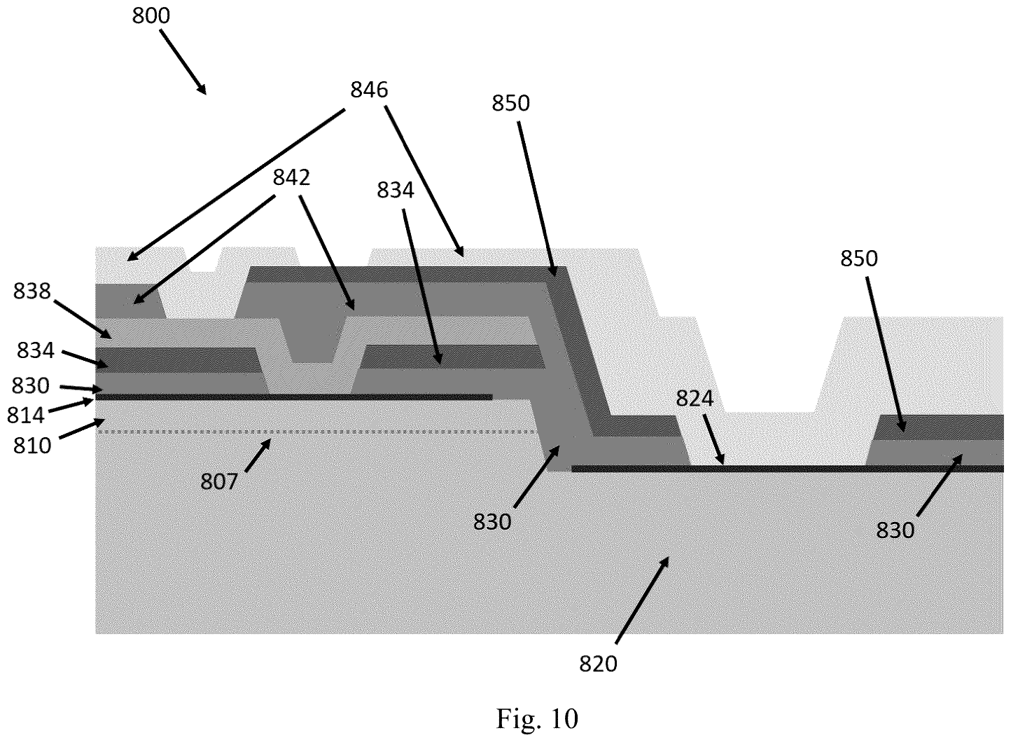

FIG. 10 shows a die according to embodiments of this invention. In addition to the DBR 834, a second DBR 846 can be deposited on the dielectric structure 842. This second DBR can be more effective in terms of reflectivity and thus flux, because in this case the second DBR is not sandwiched between the same material (i.e., two layers or structures of SiO₂). The first dielectric structure 830 and the second dielectric structure 842 may be in direct contact with each other. However, they may be deposited in separate steps from each other. In any case, they may each have a thickness (i.e., a minimum thickness throughout their structure) that is at least one wavelength of the emitted light of the die, such as from one wavelength to two wavelengths of the emitted light of the die (e.g., for blue emitted light, a thickness of from 300-600 nm; for red emitted light, a thickness of 500-800 nm).

The disclosures provided in this specification are intended to illustrate but not necessarily to limit the described implementation. As used herein, the term “implementation” means an implementation that serves to illustrate by way of embodiments but not limitation. The techniques described in the preceding text and figures can be mixed and matched as circumstances demand to produce alternative implementations. It will be apparent to those of ordinary skill in the art that numerous variations, changes, and substitutions of the embodiments described above can be made without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. All such alternatives will be apparent to one skilled in the art in light of this disclosure and are intended to fall within the scope of the appended claims.

What is claimed is:

1. A semiconductor structure comprising:
a p-doped semiconductor;
one or more first transparent conductive oxide layers directly contacting the p-doped semiconductor;
one or more first metal layers directly contacting the first transparent conductive oxide;
an n-doped semiconductor and an active layer, the n-doped semiconductor coupled to the p-doped semiconductor through the active layer;
one or more second transparent conductive oxide layers directly contacting the n-doped semiconductor; and
one or more second metal layers directly contacting the second transparent conductive oxide.

2. The semiconductor structure of claim 1, wherein the one or more first transparent conductive oxide layers and the one or more second transparent conductive oxide layers comprise a same material as each other.

3. The semiconductor structure of claim 1, wherein the one or more first transparent conductive oxide layers and the one or more second transparent conductive oxide layers comprise a different material as each other.

4. The semiconductor structure of claim 1, further comprising a first dielectric structure disposed on both the one or more first transparent conductive oxide layers and the one or more second transparent conductive oxide layers.

5. The semiconductor structure of claim 4, further comprising a distributed bragg reflector (DBR) disposed on the first dielectric structure, the DBR overlapping in the vertical direction with both the one or more first transparent conductive oxide layers and the one or more second transparent conductive oxide layers.

6. The semiconductor structure of claim 4, wherein the DBR is a first DBR, further comprising: a second DBR spaced apart from the first DBR.

7. The semiconductor structure of claim 4, further comprising a second dielectric structure disposed on the one or more first metal layers.

8. The semiconductor structure of claim 1, wherein the one or more first metal layers comprises silver.

9. The semiconductor structure of claim 1, wherein the one or more first metal layers overlaps a surface of the n-doped semiconductor.

10. The semiconductor structure of claim 1, wherein the one or more first metal layers is in direct contact with a surface of the p-doped semiconductor.

11. The semiconductor structure of claim 1, wherein the one or more second metal layers are one or more bonding layers disposed on the one or more first metal layers, the one or more bonding layers comprising at least one of Ag, Ni, Ti, and Cu.

12. The semiconductor structure of claim 1, wherein:
each of the one or more first metal layers directly contacts at least one of the one or more first transparent conductive oxide layers in a total contact area smaller than an entire area of that respective one of the one or more first metal layers, and
each of the one or more second metal layer directly contacts at least one of the one or more second transparent conductive layers in a total contact area smaller than an entire area of that respective one of the one or more second metal layers.

13. The semiconductor structure of claim 12, wherein:
each of the one or more first metal layers directly contacts the one or more first transparent conductive oxide layers at multiple contact areas discontinuous from each other, and
each of the one or more second metal layers directly contacts the one or more second transparent conductive oxide layers at multiple contact areas discontinuous from each other.

14. A method comprising:
providing a semiconductor wafer;
etching the semiconductor wafer to expose a surface of an n-doped semiconductor and form a mesa with a surface of the p-doped semiconductor;
depositing a transparent conductive oxide structure on both the n-doped semiconductor and the p-doped semiconductor; and
patterning the transparent conductive oxide structure to form one or more first transparent conductive oxide layers on the p-doped semiconductor and one or more second transparent conductive oxide layers on the n-doped semiconductor spaced apart from the one or more first transparent conductive oxide layers.

15. The method of claim 14, further comprising depositing a first dielectric structure on the one or more first and second transparent conductive oxide layers.

16. The method of claim 15, further comprising depositing a DBR on the first dielectric structure.

17. The method of claim 16, further comprising depositing one or more metal reflectors on the first dielectric structure.

18. The method of claim 17, wherein the one or more metal reflectors extends over the n-doped semiconductor.

19. The method of claim 17, further comprising depositing a second dielectric structure on the one or more metal reflectors.

20. The method of claim 15, further comprising depositing one or more bonding layers over the first dielectric structure, the one or more bonding layers comprising a metal and being in direct contact with the one or more second transparent conductive oxide layers on the n-doped semiconductor.
